(19) United States
(12) Patent Application Publication
(10) Pub. No.: US 2007/0105302 A1
(43) Pub. Date: May 10, 2007

(54) Integrated circuit formed on a semiconductor substrate

(75) Inventors: Albert Birner, Dresden (DE); Andreas Weber, Dresden (DE); Frank Ludwig, Dresden (DE); Jorg Radecker, Dresden (DE); Kimberly Wilson, Dresden (DE); Kerstin Mothes, Dresden (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 11/269,897

(22) Filed: Nov. 9, 2005

(51) Int. Cl. H01L 21/76; H01L 21/8242

(52) U.S. Cl. 438/243; 438/424; 438/427; 438/248

(57) ABSTRACT

An integrated circuit is provided, which is formed on a semiconductor substrate. The integrated circuit comprises electronic elements and isolation elements, wherein the electronic elements and the isolation elements are arranged at a top surface of the semiconductor substrate. The isolation elements each are arranged between electronic elements and electrically isolate the electronic elements from each other. Furthermore, the isolation elements comprise an upper part and a lower part, wherein the upper part is broader than the lower part.

### TECHNICAL FIELD OF THE INVENTION

The present invention relates to an integrated circuit formed on a semiconductor substrate and to a method for fabricating an integrated circuit on a semiconductor substrate.

### BACKGROUND OF THE INVENTION

Integrated electronic circuits nowadays contain millions of densely packed electronic elements—such as resistors, capacitors, or transistors. While all such elements are integrated on a single semiconductor substrate chip, the size of such a single chip is far below a squared inch. For modern integrated electronic circuits, often the number of as many as possible electronic elements on a single chip is the main figure for their overall performance.

Integration is therefore very critical and, after all, also closely related to the economic success of an integrated circuit as, for example, in the case of electronic data memories or central processing units. A prominent example for a highly integrated modem electronic circuit is an electronic data memory device, such as a dynamic random access memory (DRAM), which stores its information content in capacitors: A charged and an uncharged state of the capacitors correspond to logical states of a memory cell. One such memory cell then comprises at least a capacitor and a transistor, the transistor being a so-called selection transistor for operating and accessing the memory cell. Increasing the performance of an electronic data memory, or, in general, any other modem integrated device, translates then to integrating as many electronic elements as possible into and onto a single substrate chip.

Modern fabrication processes for manufacturing highly integrated electronic circuits, for example the CMOS process, realize electronic elements on and in a semiconductor substrate by means of a combination of lithographic, etching, deposition, and related processing techniques. Integration of electronic elements is achieved, described here as an example for a so-called trench capacitor, as follows. Firstly, a vertical trench is etched into the semiconductor substrate for forming a first electrode of the capacitor. Secondly, a dielectric is deposited on the sidewalls and the bottom of the trench, the remainder of which is then subsequently filled with a material for forming a counter electrode of said capacitor.

The semiconductor substrate is doped in the vicinity of the lower portion of the trench for providing electric conductivity for a first outer electrode. In the upper region, close to the surface of the semiconductor substrate, additional doping is conducted for establishing contact to the counter electrode, and for forming parts of a selection transistor. Since in modem highly integrated circuits the vertical distance between the upper and the lower electrode is only of the range of a few tens of nanometers, the suppression of undesired vertical parasitic currents is very critical.

Furthermore, a highly integrated device provides as many electronic elements as possible on a single substrate chip. Therefore, also horizontal parasitic currents and interference amongst neighboring capacitors, following the above example of a DRAM, have to be suppressed. For this suppression of said parasitic currents it is known in the prior art to replace parts of the upper semiconductor substrate, where no semiconductor element is required, by an insulator. In the case of a DRAM, such isolation elements are referred to as so-called shallow trench isolation (STI) elements, which are arranged between two neighboring capacitor elements. For forming such STIs, again a trench is formed by means of anisotropic etching, which is then subsequently filled by an insulator, such as a high density plasma oxide (HDP oxide). Said oxide, also referred to as an HDP fill, is a well established material for sufficiently insulating adjacent electronic elements in highly integrated electronic circuits.

As the integration of electronic circuits proceeds, the electronic elements have to be arranged more densely. As a consequence, the mean distance between electronic elements decreases, and the isolation elements have to become narrower. Since the isolation elements have to suppress both vertical and horizontal currents, these insulators have to be formed in trenches with a minimum depth and a decreasing width for said above reasons. As the aspect ratio, defined as the ratio of the trench depth over the trench width, increases, the complete filling of an isolation trench by, for example an HDP oxide, becomes more and more difficult. Usually, trenches possessing an aspect ratio above 3 cannot be filled completely anymore, and voids are incorporated into the isolation element. Whereas voids possess almost ideal electric isolation properties, they cause difficulties in the subsequent device processing, if being located in the upper part of the isolation element close to its top surface.

State of the art manufacturing of integrated circuits is therefore subject to certain limitations, these limitations regarding above all the integration of more electronic elements onto a given substrate. For further increasing the integration of electronic circuits, the electronic elements have to be arranged more closely to each other while it must be still possible to provide reliable isolation elements between adjacent electronic elements. Such isolation elements furthermore must comply with surrounding circuit elements, for their fabrication by established manufacturing processes.

### SUMMARY OF THE INVENTION

Taking the deficits of prior art, the present invention provides an improved integrated circuit, comprising electronic elements and isolation elements and a method for fabricating an improved integrated circuit, comprising electronic elements and isolation elements.

According to one embodiment of the present invention, there is an integrated circuit which is formed on a semiconductor substrate. The integrated circuit comprises electronic elements and isolation elements, which are arranged at a top surface of the semiconductor substrate. The isolation elements are arranged between electronic elements and electrically isolate adjacent electronic elements from each other. The isolation elements further comprise an upper part and a lower part, wherein said upper part is broader than the lower part.

The isolation element, comprising a broader upper part and a narrower lower part, achieves a higher overall aspect ratio compared to state of the art isolation elements. While penetrating deep enough into the substrate to suppress vertical parasitic currents, the isolation element provides also suppression of horizontal parasitic currents and is narrow enough for the electronic elements to be arranged closer to each other. Since a higher aspect ratio of the isolation element translates to a smaller width—keeping constant the height—the electronic elements can be arranged in a denser configuration and hence more electronic elements may be integrated into the circuit. This substantially increases the overall performance of the integrated circuit. The two-part configuration of the isolation element achieves said enhanced aspect ratio while allowing for an efficient and reliable fabrication of the isolation element by established manufacturing processes.

According to another embodiment of the present invention, there is an integrated memory device which is formed on a semiconductor substrate. The integrated memory device comprises memory cells and shallow trench isolation elements (STI), the memory cells comprising a trench capacitor. The memory cells and the shallow trench isolation elements are arranged at a top surface of the semiconductor substrate, wherein the shallow trench isolation elements are arranged between the trench capacitors of neighboring memory cells. The shallow trench isolation elements electrically isolate said trench capacitors. Furthermore, the shallow trench isolation elements comprise an upper part and a lower part, wherein the upper part is broader than the lower part.

The inventive integrated memory device may include an increased number of memory cells, providing an enhanced overall performance of the integrated memory device. Since the shallow trench isolation elements, comprising a broader upper part and a narrower lower part, may be manufactured with an enhanced aspect ratio, the memory cells can be arranged closer to each other. The enhanced aspect ratio still provides a height of the shallow trench isolation elements for sufficient vertical electric isolation, while being narrower for a denser packing of the memory cells. In this way, undesired both horizontal and vertical parasitic currents and interference are still suppressed.

According to still another embodiment of the present invention, a method for fabricating an integrated circuit is provided. The inventive method includes the following steps.

In a first step, a semiconductor substrate is provided. In a second step, electronic elements at a top surface of said semiconductor substrate are provided. In a next step, a first mask is provided on top of the semiconductor substrate, comprising electronic elements, wherein the first mask has at least one first opening, which is arranged between two electronic elements. In a subsequent first anisotropic etching step, a lower groove is formed at the first opening. After removing the first mask, a second mask on top of the semiconductor substrate, comprising the electronic elements and the first groove, is provided. This second mask has at least one second opening, which is arranged between two of the electronic elements. Furthermore, the second opening is larger than the first opening. In a subsequent second anisotropic etching step an upper groove in the semiconductor substrate at the second opening is formed. The second mask may be removed before the lower groove and the upper groove are filled with a filling element in a subsequent filling step. The filling of the lower groove forms a lower part of an isolation element and the filling of the upper groove forms an upper part of an isolation element. Since the width of the lower and the upper groove correspond to the respective size of the first and the second opening, the upper part of the isolation element will be broader than the lower part.

According to yet another embodiment of the present invention, a method for fabricating an integrated memory device is provided. The inventive method comprises the following steps.

In a first step, a semiconductor substrate is provided. In a second step, trench capacitors at a top surface of the semiconductor substrate are provided. The trench capacitors comprise a trench, an inner element, and an outer layer. In a first anisotropic etching step, an upper groove is etched into the semiconductor substrate between two trench capacitors. This first anisotropic etching step includes the removal of an upper part of the outer layer of the trench capacitors. In a depositing step, a liner layer is deposited, which covers the sidewalls of the upper groove. Covering the sidewalls of the upper groove, the depositing step may also result in a coverage of the bottom of the upper groove by the liner layer. In a subsequent step, this liner layer at the bottom of the upper groove may be opened. In a second anisotropic etching step, a lower groove is formed in the semiconductor substrate between the trench capacitors. Since the liner layer covers the sidewalls of the upper groove, the etching of the lower groove will result in a lower groove which is narrower than the upper groove. After removing of the liner layer, the lower groove and the upper groove are filled with a filling element in a subsequent filling step. In this way, a shallow trench isolation element is formed, which comprises a lower and an upper part, wherein the upper part is broader than the lower part.

According to another embodiment of the present invention, the height of the upper part of the isolation elements ranges from 100 to 300 nm. The height of the lower part of the isolation elements ranges, preferably, from 50 to 200 nm. An isolation element, comprising an upper broader part and a lower narrower part, with the heights in the ranges provides sufficient electric isolation and hence a sufficient suppression of vertical parasitic currents and interference.

According to still another embodiment of the present invention, the aspect ratio of the upper part ranges from 2 to 5. The aspect ratio is defined as the quotient of the height over the width of the upper part. Preferably, according to another embodiment of the present invention, the aspect ratio of the lower part ranges from 2 to 5. The aspect ratio being accordingly defined as the quotient of the height over the width of the lower part.

Hence, an aspect ratio translates a given height to a width of the isolation element. For an enhanced aspect ratio, the width can be reduced while keeping a given height. In this way, the inventive isolation elements provide a sufficient height for suppressing vertical parasitic currents and interference in combination with a reduced width and hence allow for a denser packing of electronic elements. Parasitic currents and interference is still suppressed, and the overall performance of the integrated circuit is enhanced.

According to another embodiment, the isolation element comprises a high density plasma oxide (HDP oxide). Said HDP oxide is preferably deposited and processed by established manufacturing processes for highly integrated circuits and devices. Furthermore, HDP oxide provides sufficient electric isolation of adjacent electronic elements.

According to yet another embodiment of the present invention, the isolation element comprises a void. Preferably, the void is situated mainly in the lower part of the isolation element.

If the height of an isolation element is to be maintained for a sufficient suppression of vertical parasitic currents and interference, a decreased width of the isolation elements, as a result of a denser arrangement of electronic elements, translates in an increased aspect ratio of the entire isolation element or parts thereof. Modem filling processes however, are subject to certain limitations as far as a complete filling of the entire isolation element is concerned, and hence the aspect ratio proves a critical process figure. In case of an excessive aspect ratio, the filling process is not able anymore to completely fill an etched structure, and voids are incorporated in the filling material. Although—in the case of isolation elements—voids provide ideal electric isolation, they pose certain problems to later process stages, which are based on the integrated device comprising the isolation element at its top.

The present invention provides a void for electric isolation within the isolation element, preferably, situated mainly in the lower part of the isolation element. Although a filling process may not provide complete filling, the invention places a void at the lower part of an isolation element, hence providing both electrical isolation and an undisturbed top surface of the isolation element for further standard processing of the integrated circuit. Hence, failure-free manufacturing of the integrated circuit and memory device with standard established process techniques is provided, and an enhanced device performance of the ready integrated circuit is achieved.

According to still another embodiment of the present invention, grooves and trenches are etched into the semiconductor substrate by means of a plasma enhanced etching process. Such plasma enhanced etching techniques, such as reactive ion etching (RIE), are established processing techniques for achieving reproducible and high quality results. An improved integrated circuit and an efficient manufacturing thereof are provided, due to the application of well established processes.

### BRIEF DESCRIPTION OF THE DRAWINGS

The invention is described below in more detail with reference to the various embodiments and drawings, in which:

FIG. 1 shows an integrated circuit having electronic elements, according to a first embodiment of the present invention.

FIG. 2 shows a sectional view of electronic elements in an integrated device, according to prior art in panels A and B, according to a second embodiment of the present invention in panel C, and according to a third embodiment of the present invention in panel D.

FIG. 3 shows a top view of an integrated circuit according to a fourth embodiment of the present invention.

FIG. 4 shows a sectional view of an electronic element, according to a fifth embodiment of the present invention.

FIG. 5 shows a sectional view of an electronic element during manufacturing in panels A through D, according to a sixth embodiment of the present invention.

FIG. 6 shows a sectional view of an isolation element during manufacturing in panels A through C, according to a seventh embodiment of the present invention.

FIG. 7 shows a sectional view of an isolation element during manufacturing in panels A through C, according to an eighth embodiment of the present invention.

### DETAILED DESCRIPTION OF THE INVENTION

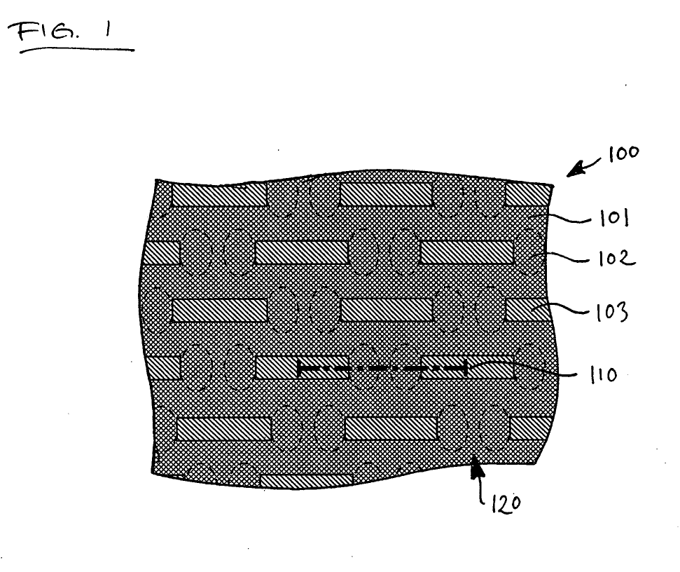

FIG. 1 shows a schematic top view of an integrated circuit 100, with a facing isolation layer 101 and integrated access elements 103, formed, for example, from silicon. Electronic elements are buried underneath the circuit surface, and are denoted by the broken-lined sections 102. As can be seen from the circuit layout, the electronic elements are arranged in pairs 120. The access elements 103 are coupled to two electronic elements of adjacent pairs.

The present layout may be regarded as an arrangement of memory cells, for example. The corresponding electronic elements may then be arranged underneath the broken-lined sections 102. In a typical layout of a dynamic random access memory (DRAM), memory cells may be arranged as such. The line 110 marks the position of a pair of electronic elements and two halves of the respective access elements 103.

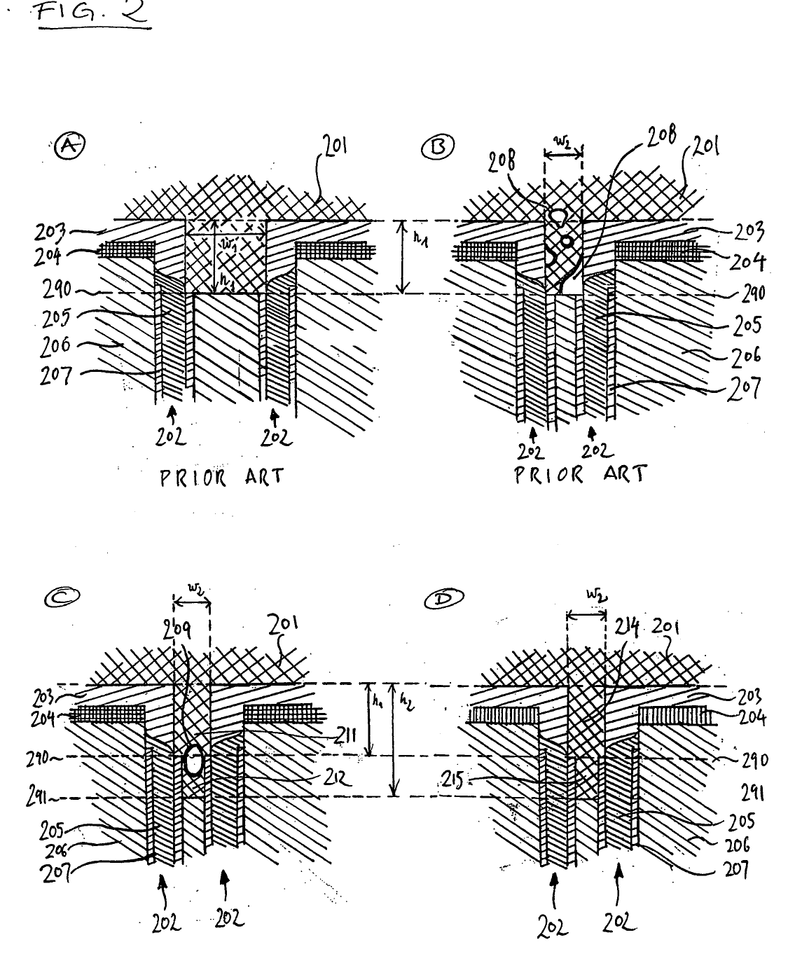

FIG. 2 shows in panels A through D a sectional view of the buried electronic elements, which may be along the line 110 of FIG. 1. Following the example of a DRAM, the electronic elements may comprise two trench capacitors 202 which are—in this case—arranged in pairs. The trench capacitors 202 are formed in a semiconductor substrate 206 and comprise a dielectric 207. A filling element 205 represents an electrode of the capacitor 202. Usually, a functional integrated device further comprises additional elements for operation, such as contacting elements 204 and covering elements 203.

In panel A, according to prior art, an isolation element 201 electrically isolates the two capacitors 202 with a section between the two capacitors. The section between the two capacitors 202 has a height h₁ and a width w₁, the height h₁ being also marked with the line 290.

For a reliable manufacturing of the isolation element 201, the aspect ratio h/w, defined as the quotient of a height h over a width w, may not exceed a critical value. This restriction poses limitations on how close two neighboring capacitors 202 may be arranged and hence limits integration, since a minimum height h is to be maintained for a suppression of vertical interference.

In panel B, according to prior art, the width w₂ of the section of the isolation element 201, which separates the two trench capacitors 202, has been decreased in respect to w₁, for achieving a denser packing of the capacitors 202. As a consequence, the aspect ratio is increased, since h₁ is to be maintained. This increased aspect ratio may result in an incomplete filling, and hence voids 208 form in the isolation element 201 between the trench capacitors 202.

These voids 208, above all those close to the surface, may cause problems in the further processing. Although voids 208 are advantageous, as far as the electric isolation properties are concerned, they have to be avoided in the upper sections of the isolation element 201 to allow for an undisturbed onward processing of the integrated device.

Panel C shows a schematic sectional view, in which the central part of the semiconductor substrate 206 has been reduced relatively to the central facing dielectric elements 207. The central section of the isolation element 201 is hence divided into an upper part 211 and a lower part 212 with an overall height h₂, which has been also marked by the line 291. By means of this two-part configuration with an increased aspect ratio, an advantageous void 209 is formed mainly in the lower part 212 of the isolation element 201, where it provides electric isolation and is situated remote enough from the surface and hence not causing problems during onward processing. Since there exists now a location where voids preferably and advantageously form, the upper section 211 may be completely filled by standard deposition techniques and voids in the upper section are avoided.

Panel D shows a further sectional view of the trench capacitors 202 with the isolation element 201, which is completely filled between the capacitors 202. The filling comprises a broader upper part 214 and a lower narrower part 215, formed by a filling process that is able to fill structures with an increased aspect ratio. The two-part configuration of the central isolation element allows for a higher overall aspect ratio h₂/w₂ and hence for a denser packing of the trench capacitors 202, and, ultimately, to an enhanced overall device performance.

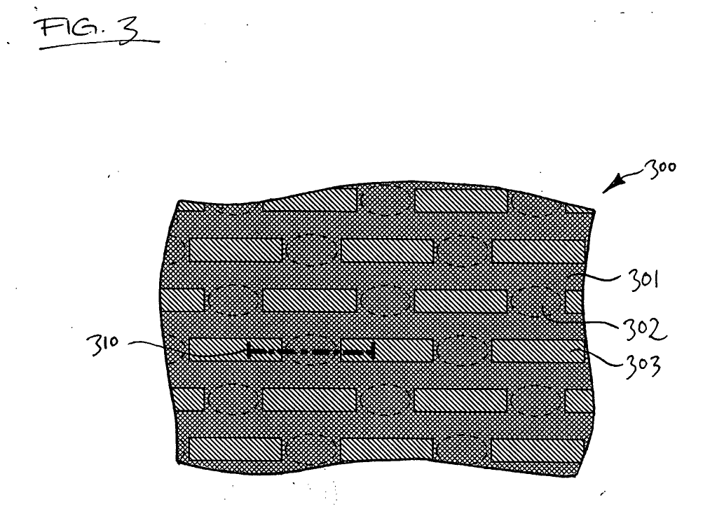

FIG. 3 shows a top view of an integrated device 300, with a top surface 301 that comprises access elements 303. The integrated device 300 comprises buried electronic elements, which are denoted by the broken-lined sections 302. One of these electronic elements and two respective parts of the access elements 303 are marked by the line 310. This arrangement of electronic elements may correspond to modem electronic data memories, in which the electronic elements correspond to memory cells that are buried at the location of the broken lined sections 302. The access elements 303 then may provide access to the logical state of the buried memory cells by means of applying electrical signals.

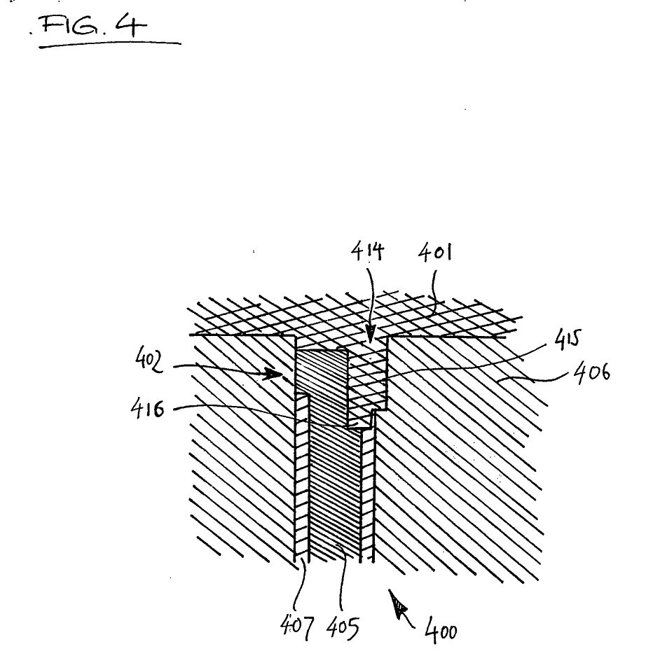

FIG. 4 shows a sectional view of an electronic element 400 comprising a central element 405 and a covering element 407, arranged mainly in a substrate 406. In order to achieve electric contact to the central element 405, said element 405 is coupled to the substrate 406 at an upper region 402. An isolation element 401 may, on the other side, provide electrical isolation from neighboring electronic elements by providing a trench section 414. Said trench section 414 comprises a broader upper part 415 and a narrower lower part 416. This two-part configuration of the isolation element 414 allows for a manufacturing with an increased aspect ratio, hence a narrower section 414 for a given height, and, ultimately, to a denser packing of electronic elements.

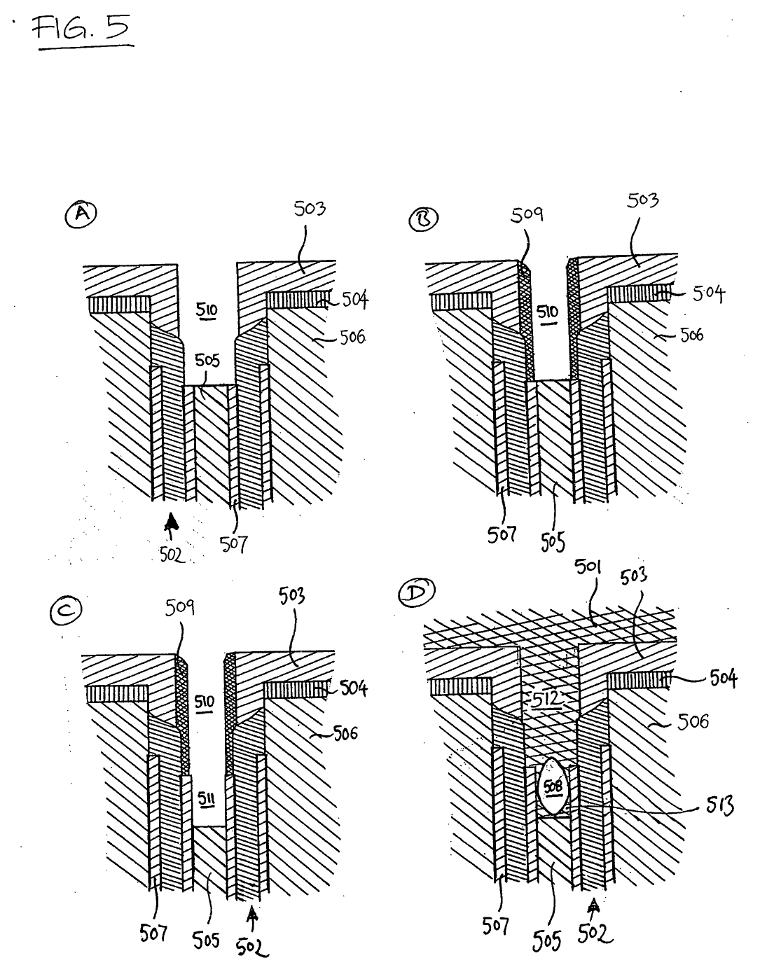

FIG. 5 illustrates schematically the fabrication of a device, similar to the setup as descried in conjunction with panel C of FIG. 2. Panel A shows a pair of trench capacitors 502, comprising a dielectric element 507. The central part of the substrate 506 between the two capacitors 502 is denoted by 505. Further access elements 504 and filling elements 503 are arranged on top of the substrate 506. A first trench 510 is formed between the trench capacitors, for example by means of anisotropic etching. The central part of the semiconductor substrate 505 is evenly leveled with the respective dielectric parts 507 to form an even ground of the first trench 510.

After the deposition of a liner element 509, at least the sidewalls of the first trench 510 are covered by the liner element 509, as shown in panel B. The liner element 509 reaches down to the bottom of the first trench 510. It further covers the top surface of the central dielectric elements 507. The liner element 509 may also have covered the central isolation element 505 during an earlier process stage, but the liner has been opened in order to provide direct access to the substrate 505 for the subsequent etching.

After carrying out a second etching step for forming a second groove 511, only the central part 505 of the semiconductor substrate 506 is consequently reduced, as shown in panel C. The liner element 509 acts as a mask and prevents that the central dielectric elements 507 are reduced, which hence remain mainly untouched by this, often anisotropic, etching process. The removal of the liner element 509 forms a broader upper section of the trench 510 and a lower narrower section 511.

After filling said trenches 510 and 511 with a filling element 501, a central isolation element is formed, comprising a broader upper section 512 and a lower narrower section 513, as shown in panel D. The central isolation element may further comprise a void 508, preferably arranged mainly in the lower isolation element 513. In this way, the aspect ratio of the central isolation element may be increased, with a decreased width while maintaining the height of the central isolation element for suppression of vertical parasitic currents and interference.

Although the aspect ratio may be too high for the filling process to be able to fill completely both trenches 510 and 511, the two-part configuration may result in a void 508, which is arranged mainly in the lower section 513. The upper section 510 may then be filled again completely by a filling process to form a homogeneous upper isolation element 512, without voids close to the surface.

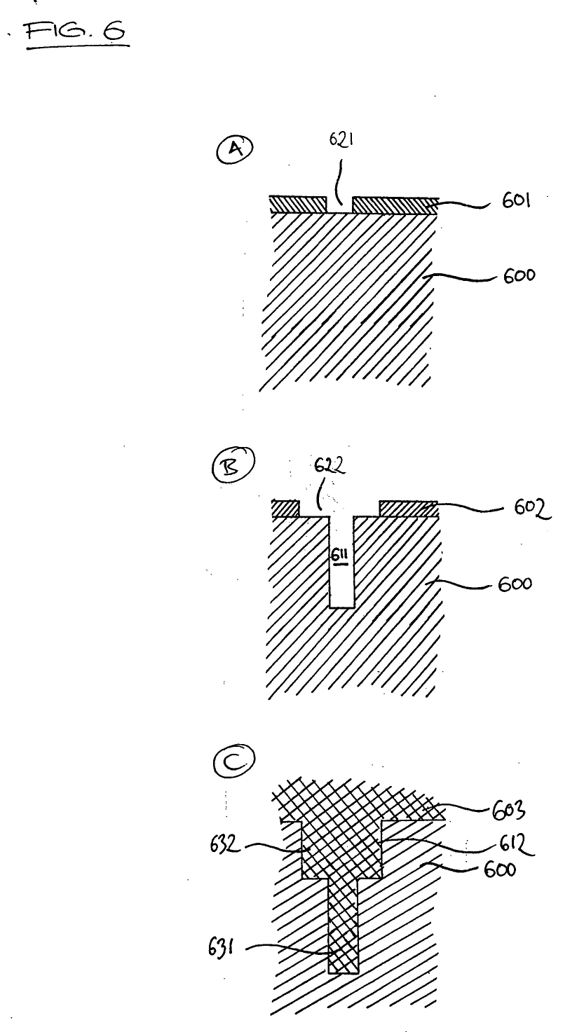

FIG. 6 shows in panels A through C schematically the formation of a two part isolation element in a substrate 600. Firstly, as shown in panel A, a first mask 601 with a first opening 621 is formed on top of the substrate 600. A subsequent anisotropic etching step results in a first narrow trench 611. Subsequently, a second mask 602 with a second opening 622 is formed, as shown in panel B, wherein the second opening 622 is larger than the first opening 621. A second anisotropic etching step will therefore result in a broader upper trench 612, while continuing the etching of the narrower part 611.

By filling said trenches with a filling element 603, as shown in panel C, a two-part isolation element is formed. Said two-part isolation element comprises a broader upper part 632 and a narrower lower part 631.

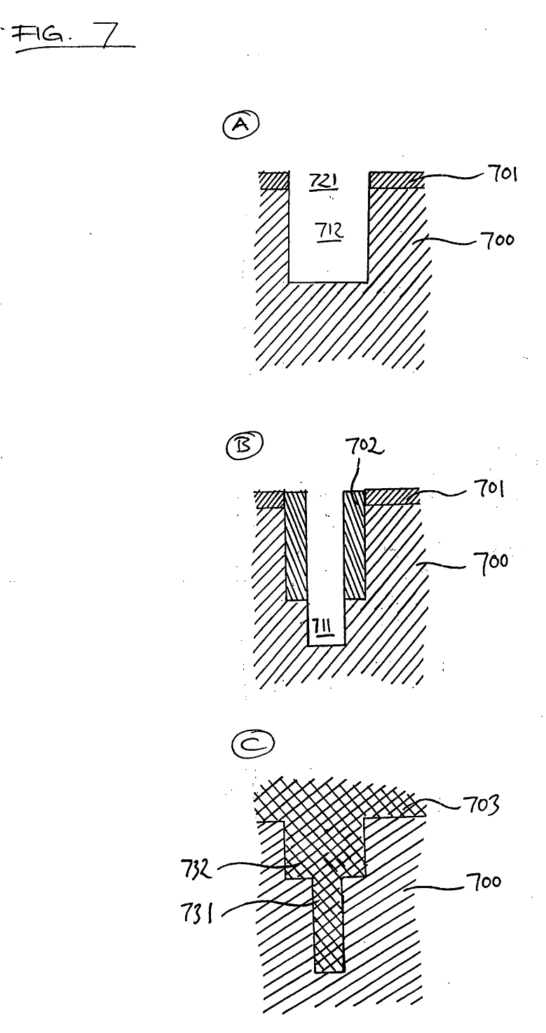

FIG. 7 shows in panels A through C a related manufacturing process for forming a two-part isolation element, similarly to the one shown in conjunction with FIG. 6. In a first step, a first mask 701 on top of a substrate 700 with a first opening 721 is formed. After a first anisotropic etching step, as shown in panel A, a first trench 712 is formed. By covering the sidewalls of the first trench 712 with a liner element 702, the opening of the bottom of the first trench 712 is reduced. A second anisotropic etching step will therefore result in a narrower second trench 711. After removing the liner element 702, filling the trenches 711 and 712 with a filling element 703, again, results in a two-part structure. This two-part structure then comprises an upper broader section 732 and a narrower lower section 731.

The preceding description only describes advantageous exemplary embodiments of the invention. The features disclosed therein and the claims and the drawings can, therefore, be essential for the realization of the invention in its various embodiments, both individually and in any combination.

What is claimed is:

1. An integrated circuit formed on a semiconductor substrate, comprising:
electronic elements and isolation elements, the electronic elements and isolation elements being arranged in the semiconductor substrate at a top surface of the semiconductor substrate, the isolation elements each being arranged between electronic elements and electrically isolating the electronic elements from each other, wherein the isolation elements comprise an upper part and a lower part, the upper part being broader than the lower part.

2. The integrated circuit as claimed in claim 1, wherein a height of the upper part of the isolation element ranges from 100 to 300 nm.

3. The integrated circuit as claimed in claim 1, wherein a height of the lower part of the isolation element ranges from 50 to 200 nm.

4. The integrated circuit as claimed in claim 2, wherein an aspect ratio of the upper part ranges from 2 to 5, the aspect ratio being defined as a quotient of the height over width of the part of the isolation element.

5. The integrated circuit as claimed in claim 3, wherein an aspect ratio of the lower part ranges from 2 to 5, the aspect ratio being defined as the quotient of the height over the width of the part of the isolation element.

6. The integrated device as claimed in claim 1, wherein the isolation element comprises a high density plasma oxide.

7. The integrated circuit as claimed in claim 1, wherein the isolation element comprises a void.

8. The integrated circuit as claimed in claim 7, wherein the void is situated mainly in the lower part of the isolation element.

9. An integrated memory device formed on a semiconductor substrate, comprising:
memory cells and shallow trench isolation elements, each memory cell comprising a trench capacitor, the memory cells and shallow trench isolation elements being arranged in the semiconductor substrate at a top surface of the semiconductor substrate, the shallow trench isolation elements each being arranged between the trench capacitors of the memory cells and electrically isolating the trench capacitors, wherein the shallow trench isolation elements comprise an upper part and a lower part, the upper part being broader than the lower part.

10. The integrated memory device as claimed in claim 9, wherein a height of the upper part of the shallow trench isolation elements ranges from 100 to 300 nm.

11. The integrated memory device as claimed in claim 9, wherein a height of the lower part of the shallow trench isolation elements ranges from 50 to 200 nm.

12. The integrated memory device as claimed in claim 10, wherein an aspect ratio of the upper part ranges from 2 to 5, the aspect ratio being defined as the quotient of the height over the width of the part of the shallow trench isolation element.

13. The integrated memory device as claimed in claim 11, wherein an aspect ratio of the lower part ranges from 2 to 5, the aspect ratio being defined as the quotient of the height over width of the part of the shallow trench isolation element.

14. The integrated memory device as claimed in claim 9, wherein the shallow trench isolation element comprises a high density plasma oxide.

15. The integrated memory device as claimed in claim 9, wherein the shallow trench isolation element comprises a void.

16. The integrated memory device as claimed in claim 7, wherein the void is situated substantially in the lower part of shallow trench isolation element.

17. A method for fabricating an integrated circuit, comprising:
providing a semiconductor substrate;
providing electronic elements in the semiconductor substrate at a top surface of the semiconductor substrate;
providing a first mask on top of the semiconductor substrate comprising the electronic elements, the first mask having at least one first opening being arranged between two of the electronic elements;
a first anisotropic etching step for etching the semiconductor substrate at the first opening of the first mask for forming a lower groove;
removing the first mask;
providing a second mask on top of the semiconductor substrate comprising the electronic elements, the second mask having at least one second opening being arranged between two of the electronic elements, the second opening being larger than the first opening;
a second anisotropic etching step for etching the semiconductor substrate at the second opening of the second mask for forming an upper groove;
filling the lower groove and the upper groove with a filling element, such that filling of the lower groove forms a lower part of an isolation element and the filling of the upper groove forms an upper part of the isolation element, the upper part being broader than the lower part.

18. The method as claimed in claim 17, wherein the first anisotropic etching step is carried out by means of plasma enhanced etching process.

19. The method as claimed in claim 17, wherein the second anisotropic etching step is carried out by means of plasma enhanced etching process.

20. The method as claimed in claim 17, wherein the isolation element is provided by filling said grooves with a high density plasma oxide.

21. The method as claimed in claim 17, wherein the first anisotropic etching step and the second anisotropic etching step are carried out, such that height of the lower groove ranges from 50 to 200 nm and the height of the upper groove ranges from 100 to 300 nm.

22. The method as claimed in claim 17, wherein the first anisotropic etching step and the second anisotropic etching step are carried out, such that an aspect ratio of the lower groove ranges from 2 to 5, the aspect ratio being defined as the quotient of height over the width of the lower groove.

23. The method as claimed in claim 17, wherein the first anisotropic etching step and the second anisotropic etching step are carried out, such that an aspect ratio of the upper groove ranges from 2 to 5, the aspect ratio being defined as the quotient of height over the width of the upper groove.

24. The method as claimed in claim 17, wherein the isolation element comprises a void, he void being situated mainly in the lower part of the isolation element.

25. A method for fabricating an integrated memory device, comprising:
providing a semiconductor substrate;
providing trench capacitors in the semiconductor substrate at a top surface of the semiconductor substrate, the trench capacitors comprising a trench, an inner element, and an outer layer;
a first anisotropic etching step for etching an upper groove into the semiconductor substrate between two of the trench capacitors, including the removal of an upper part of the outer layer of the trench capacitors;
depositing a liner layer covering the sidewalls of the upper groove;
opening the liner at the bottom of the upper groove;
a second anisotropic etching step for etching a lower groove into the semiconductor substrate between the trench capacitors;
removing the liner layer;
filling the lower groove and the upper groove with a filling element, such that filling of the lower groove forms a lower part of a shallow trench isolation element and the filling of the upper groove forms an upper part of the shallow trench isolation element, the upper part being broader than the lower part.

26. The method as claimed in claim 25, wherein the first anisotropic etching step is carried out by means of plasma enhanced etching process.

27. The method as claimed in claim 25, wherein the second anisotropic etching step is carried out by means of plasma enhanced etching process.

28. The method as claimed in claim 25, wherein the shallow trench isolation element is provided by filling the grooves with a high density plasma oxide.

29. The method as claimed in claim 25, wherein the first anisotropic etching step and the second anisotropic etching step are carried out, such that height of the lower groove ranges from 50 to 200 nm and the height of the upper groove ranges from 100 to 300 nm.

30. The method as claimed in claim 29, wherein the first anisotropic etching step and the second anisotropic etching step are carried out, such that an aspect ratio of the lower groove ranges from 2 to 5, the aspect ratio being defined as the quotient of the height over the width of the lower groove.

31. The method as claimed in claim 29, wherein the first anisotropic etching step and the second anisotropic etching step are carried out, such that an aspect ratio of the upper groove ranges from 2 to 5, the aspect ratio being defined as a quotient of the height over width of the upper groove.

32. The method as claimed in claim 25, wherein the shallow trench isolation element comprises a void, the void being situated mainly in the lower part of the shallow trench isolation element.
